(19) United States
(12) Patent Application Publication
(10) Pub. No.: US 2025/0275375 A1
(43) Pub. Date: Aug. 28, 2025

(54) DISPLAY DEVICE

(71) Applicant: LG Display Co., Ltd., Seoul (KR)

(72) Inventors: Ho-Jin KIM, Seoul (KR); Jinhyeon KIM, Goyang-si (KR); Bongchoon KWAK, Paju-si (KR)

(73) Assignee: LG Display Co., Ltd., Seoul (KR)

(21) Appl. No.: 19/006,741

(22) Filed: Dec. 31, 2024

(30) Foreign Application Priority Data
Feb. 22, 2024 (KR) 10-2024-0026124

(51) Int. Cl. H10K 59/122; H10K 59/124

(52) U.S. Cl. CPC H10K 59/122; H10K 59/124

(57) ABSTRACT

A display device can include a silicon substrate having a plurality of sub pixels, an insulating layer on the silicon substrate, and a light emitting diode disposed to correspond to each of the plurality of sub pixels. The light emitting diode includes a first electrode disposed on the insulating layer, an organic material layer on the first electrode, and a second electrode on the organic material layer. The display device can further include a plurality of inorganic bank layers covering an edge of the first electrode. The plurality of inorganic bank layers is disposed adjacent to at least the first electrode to form a step. The display device of the present disclosure may suppress flow of a lateral leakage current in a sub pixel.

### CROSS-REFERENCE TO RELATED APPLICATIONS

This application claims priority to Korean Patent Application No. 10-2024-0026124 filed on Feb. 22, 2024, in the Korean Intellectual Property Office, the entire contents of which is hereby expressly incorporated by reference into the present application.

### BACKGROUND

### Field

The present disclosure relates to a display device, and more particularly, to a display device which suppresses a flow of a lateral leakage current in a sub pixel.

### Discussion of the Related Art

Recently, interest in high resolution organic light emitting display devices for augmented reality (AR) and virtual reality (VR) mobile devices is increasing. The high efficiency is needed for the AR/VR mobile devices to ensure a high battery driving time. Further, the AR/VR mobile devices need high frame rates and short duty ratios for vivid depictions, so that high luminance operation characteristics are needed in a short period of time. Therefore, an organic light emitting display device with an organic light emitting diode (OLED) on Si-wafer (OLEDOS) structure is applied to the AR/VR mobile device.

The organic light emitting display device with the OLED on Si-wafer (OLEDOS) structure can be implemented by forming an organic light emitting diode on a back plane using a silicon wafer. At this time, the organic light emitting display device with the OLEDOS structure is implemented by applying a tandem structure in which two or more emission layers are laminated, rather than a fine metal mask (FMM), to ensure the small size and the high resolution.

The organic light emitting diode with a tandem structure has a disadvantage that a driving voltage is increased. Further, two or more stacks of the tandem structure are formed as a common layer so that a current can be leaked from any one sub pixel to an adjacent sub pixel. A color gamut can be degraded due to the leakage current. Further, the leakage current can occur also in one sub pixel so that an emission layer located on the bank emits light, which can degrade the luminance and the color purity.

### SUMMARY OF THE DISCLOSURE

An object to be achieved by the present disclosure is to provide a display device which suppresses a leakage current generated between sub pixels.

Another object to be achieved by the present disclosure is to provide a display device which suppresses an emission layer located on a bank from emitting light due to a leakage current in one sub pixel.

Still another object to be achieved by the present disclosure is to provide a display device with an OLEDOS structure in which a color gamut and a color purity are improved.

Objects of the present disclosure are not limited to the above-mentioned objects, and other objects, which are not mentioned above, can be clearly understood by those skilled in the art from the following descriptions.

According to an aspect of the present disclosure, a display device includes a silicon substrate including a plurality of sub pixels; an insulating layer on the silicon substrate; a light emitting diode disposed so as to correspond to each of the plurality of sub pixels, and including a first electrode disposed on the insulating layer, an organic material layer on the first electrode, and a second electrode on the organic material layer; and a plurality of inorganic bank layers covering an edge of the first electrode, where the plurality of inorganic bank layers is disposed adjacent to at least the first electrode to form a step.

Other detailed matters of the example embodiments of the present disclosure are included in the detailed description and the drawings.

According to aspects of the present disclosure, the display device can suppress the leakage current generated between the sub pixels by a trench structure between the sub pixels.

According to aspects of the present disclosure, the display device uses a plurality of inorganic bank layers with different widths to solve a problem in that a leakage current is generated on the bank in one sub pixel to cause the emission layer on the bank which is not the emission area to emit light.

Further, according to aspects of the present disclosure, a display device with an OLEDOS structure with improved color gamut and color purity can be implemented.

The effects according to aspects of the present disclosure are not limited to the contents exemplified above, and more various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic plan view of a display device according to an example embodiment of the present disclosure;

FIG. 2 is a schematic cross-sectional view along line II-II′ of FIG. 1;

FIG. 3 is a schematic enlarged plan view of an area A of FIG. 1; and

FIG. 4 is an image obtained by capturing a cross-section of a display device according to an example embodiment of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the disclosure. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”.

When an element or layer is disposed “on” another element or layer, another layer or another element can be interposed directly on the other element or therebetween.

Although the terms “first”, “second”, and the like are used for describing various components, these components are not confined by these terms. These terms are merely used for distinguishing one component from the other components, and may not define order or sequence. Therefore, a first component to be mentioned below can be a second component in a technical concept of the present disclosure.

Like reference numerals generally denote like elements throughout the disclosure. Further, the term “can” fully encompasses all the meanings and coverages of the term “may.”

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to example embodiments of the present disclosure will be described in detail with reference to accompanying drawings. All the components of each display device according to all embodiments of the present disclosure are operatively coupled and configured.

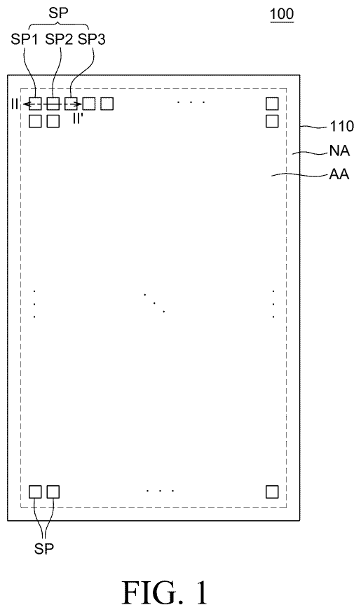

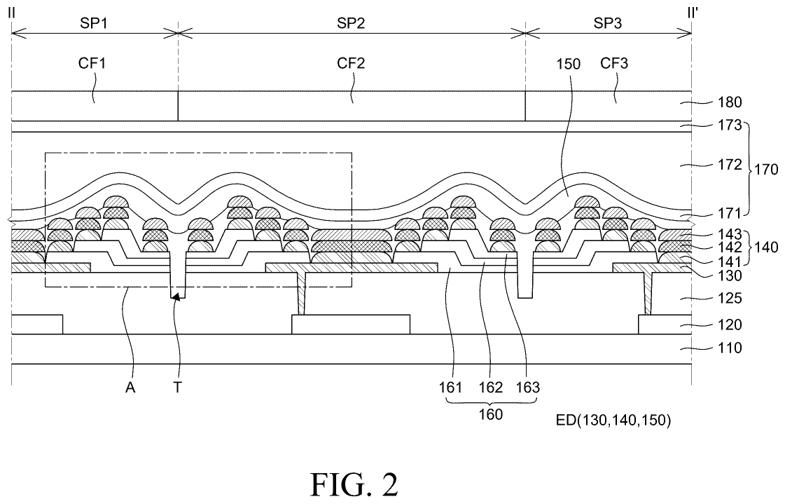

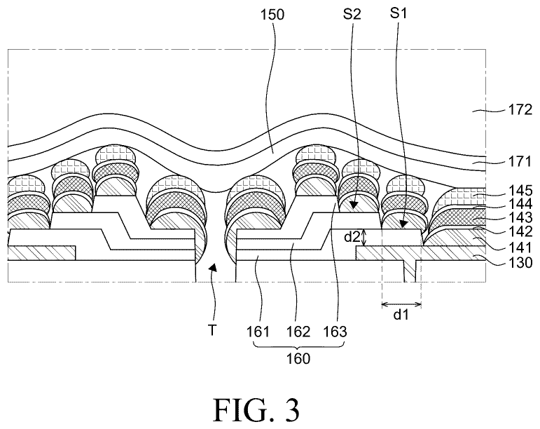

FIG. 1 is a schematic plan view of a display device according to an example embodiment of the present disclosure. FIG. 2 is a schematic cross-sectional view along line II-II′ of FIG. 1. FIG. 3 is a schematic enlarged plan view of an area A of FIG. 2. In FIG. 1, for the convenience of description, among various components of the display device 100, only a silicon substrate 110 and a plurality of sub pixels SP are illustrated.

Referring to FIGS. 1 to 3, a display device 100 according to the example embodiment of the present disclosure includes a silicon substrate 110, a driving circuit layer 120, a light emitting diode ED, a bank 160, an encapsulation layer 170, and a color filter 180. Hereinafter, for the convenience of description, the display device 100 according to the example embodiment of the present disclosure is assumed as an organic light emitting display device, but it is not limited thereto.

The silicon substrate 110 can be a support member for supporting other components of the display device 100. At this time, the silicon substrate 110 can be a silicon wafer substrate. For example, the display device 100 of the present disclosure has an OLED on Si-wafer (OLEDOS) structure in which a driving circuit layer 120 including a complementary metal oxide semiconductor (CMOS) transistor and a light emitting diode ED are integrated on a silicon wafer substrate.

The silicon substrate 110 includes an active area AA (or display area) and a non-active area NA (or non-display area). The non-active area NA can surround the active area AA entirely or only in part(s).

The active area AA is an area in which images are displayed in the display device 100. In the active area AA, a plurality of sub pixels SP which displays images and a driving circuit for driving the plurality of sub pixels SP can be disposed.

Each of the plurality of sub pixels SP is an individual unit which emits light and can include a first sub pixel SP1, a second sub pixel SP2, and a third sub pixel SP3 which emit light with different wavelengths. For example, the first sub pixel SP1 can be a blue sub pixel which emits blue light, the second sub pixel SP2 can be a green sub pixel which emits green light, and the third sub pixel SP3 can be a red sub pixel which emits red light. However, the present disclosure is not limited thereto. The light emitting diode ED can be disposed in each of the plurality of sub pixels SP.

The driving circuit can include various transistors, storage capacitors, and wiring lines for driving the plurality of light emitting diodes ED. For example, the driving circuit can be configured by various components, such as a driving transistor, a switching transistor, a sensing transistor, a storage capacitor, a gate line, and a data line, but is not limited thereto.

The non-active area NA is an area where no image is displayed. Various components for driving the sub pixels SP disposed in the active area AA can be disposed in the non-active area NA. For example, in the non-active area NA, various driving integrated circuits (ICs), such as a gate driver IC and a data driver IC, a driving circuit, a signal line, a flexible film, and the like can be disposed. Even though in FIG. 1, it is illustrated that the non-active area NA encloses the active area AA, it is not limited thereto.

The display device 100 can be configured as a top emission type. Specifically, in the display device 100, light can be emitted to the front surface of the silicon substrate 110. According to the top emission type, light emitted from the light emitting diode ED passes through a second electrode 150 of the light emitting diode ED to upwardly emit. Therefore, the second electrode 150 can have transparent or translucent characteristics. Further, a reflective layer which reflects light emitted from light emitting units 141, 143, and 145 toward a second electrode 150 can be disposed below the first electrode 130.

The driving circuit layer 120 is disposed on the silicon substrate 110. The driving circuit layer 120 can include various driving elements and wiring lines for driving the light emitting diodes ED. For example, the driving circuit layer 120 includes various components, such as a transistor, a storage capacitor, a gate line, or a data line.

The transistor can include a driving transistor, a switching transistor, and a sensing transistor. The transistor is disposed in each of the plurality of sub pixels SP to be used as a driving element of the display device 100. The driving transistor is switched according to a data voltage supplied from the switching transistor to serve to generate a data current from a power supplied from a power line and supply the data current to the first electrode. The switching transistor is switched according to a gate signal supplied to a gate line to serve to supply the data voltage supplied from the data line to the driving transistor. The sensing transistor serves to sense a threshold voltage deviation of the driving transistor which causes the image quality degradation and supplies a current of the driving transistor to a reference line in response to a sensing control signal supplied from the gate line or a separate sensing line. Here, the transistor can be configured by a complementary metal oxide semiconductor (CMOS) transistor.

An insulating layer 125 is disposed on the driving circuit layer 120. For example, the insulating layer can be formed of an organic film, such as acryl resin, epoxy resin, phenolic resin, polyamide resin, or polyimide resin. Alternatively, the insulating layer 125 can be formed of an inorganic film, such as silicon nitride, aluminum nitride, zirconium nitride, titanium nitride, hafnium nitride, nitride, tantalum silicon oxide, aluminum oxide, or titanium oxide.

The insulating layer 125 can serve as a cavity control layer which amplifies light emitted from each sub pixel SP and improves a luminous efficiency.

Specifically, a reflective layer can be disposed between the driving circuit layer 120 and the first electrode 130 to upwardly emit light which is downwardly emitted from the organic light emitting diode ED. The reflective layer can be formed of a metal material having excellent reflectivity. For example, the reflective layer can be formed of a material such as aluminum (Al), silver (Ag), silver alloy, copper (Cu), and magnesium-silver alloy (Mg: Ag), but is not limited thereto.

Therefore, the insulating layer 125 disposed between the reflective layer and the first electrode 130 can be configured to form a structure to implement a micro-cavity. At this time, positions of the reflective layer can be differently configured in each sub pixel and in this case, the insulating layer 125 between the reflective layer and the first electrode 130 can have different thicknesses. Therefore, each sub pixel SP can have a structure to implement a micro cavity corresponding to light emitted from the corresponding sub pixel SP. Further, a plurality of insulating layers 125 can be formed to differently configure positions of the reflective layer in each sub pixel SP.

In a boundary area between the respective sub pixels SP, a trench T is provided in the insulating layer 125. The trench T is provided in an area between a bank 160 which covers an end of the first electrode 130 of the first sub pixel SP1 and a bank 160 which covers an end of the first electrode 130 of the second sub pixel SP2 and an area between a bank 160 which covers an end of the first electrode 130 of the second sub pixel SP2 and a bank 160 which covers an end of the first electrode 130 of the third sub pixel SP3. The trench T can extend to a predetermined area in the insulating layer 125 without passing through the insulating layer 125. However, it is not necessarily limited thereto and the trench T passes through the insulating layer 125 and can extend to a predetermined area in the driving circuit layer 120 therebelow.

The light emitting diode ED is disposed on the insulating layer 125. The light emitting diode ED includes a first electrode 130, a plurality of organic material layers 140, and a second electrode 150.

The first electrode 130 can be an anode electrode and the second electrode 150 can be a cathode electrode. Further, the first electrode 130 can be separated for each of the plurality of sub pixels SP and light emitting units 141, 143, and 145, charge generation layers 142 and 144, and the second electrode 150 can be a common layer which is formed as one layer over the front surface of the silicon substrate 110.

The first electrode 130 is disposed on the insulating layer 125. The first electrode 130 is patterned for each of the first sub pixel SP1, the second sub pixel SP2, and the third sub pixel SP3. The first electrode 130 supplies holes to the light emitting units 141, 143, and 145 so that the first electrode can be formed of a transparent conductive material having a high work function. Specifically, the first electrode 130 can supply holes to a first light emitting unit 141 among the light emitting units 141, 143, and 145. For example, the first electrode 130 can be formed of transparent conductive material, such as tin oxide (TO), zinc oxide (ZnO), indium tin oxide (ITO), indium zinc oxide (IZO), and indium tin zinc oxide (ITZO), but is not limited thereto.

The plurality of organic material layers 140 is disposed between the first electrode 130 and the second electrode 150. The plurality of organic material layers 140 is an area where light is emitted by the coupling of electrons and holes supplied from the first electrode 130 and the second electrode 150.

Here, the plurality of organic material layers 140 has a stacked structure in which the plurality of light emitting units 141, 143, and 145 and at least one charge generation layers 142 and 144 are laminated. Referring to FIG. 2, each sub pixel SP1, SP2, or SP3 has a triple stack structure including a first light emitting unit 141 including a first emission layer, a first charge generation layer 142, a second light emitting unit 143 including a second emission layer, a second charge generation layer 144, and a third light emitting unit 145 including a third emission layer. Even though in FIG. 3, a triple stack structure in which the light emitting diode ED has three light emitting units has been described as an example, but the light emitting diode ED can have a double stack structure having two light emitting units. Hereinafter, for the convenience of description, it is assumed that the display device 100 according to the example embodiment of the present disclosure includes a light emitting diode with a triple stack structure, but it is not limited thereto.

The plurality of light emitting units 141, 143, and 145 is disposed between the first electrode 130 and the second electrode 150. The light emitting units 141, 143, and 145 are areas where light is emitted by the coupling of electrons and holes supplied from the first electrode 130 and the second electrode 150. The light emitting units 141, 143, and 145 can be white emission layers which emit white light. The white light emitted from the light emitting units 141, 143, and 145 can be converted into any one of red, green, and blue by the color filter 180. The plurality of light emitting units 141, 143, and 145 can include a first light emitting unit 141, a second light emitting unit 143, and a third light emitting unit 145.

The first light emitting unit 141 is disposed on the first electrode 130. The first light emitting unit 141 can include at least one layer of a hole injection layer, a first hole transport layer, a first emission layer, and a first electron transport layer.

The hole injection layer is disposed on the first electrode 130 to smoothly inject holes. The hole injection layer can be formed of any one or more of HAT-CN(dipyrazino[2,3-f:2′,3′-h]quinoxaline-2,3,6,7,10.11-hexacarbonitrile), CuPc(phthalocyanine), and NPD(N,N′-bis(naphthalene-1-yl)-N,N′-bis(phenyl)-2,2′-dimethylbenzidine).

The first hole transport layer HTL1 is disposed on the hole injection layer to smoothly transmit holes to the emission layer. For example, the first hole transport layer can be formed of any one or more of NPD(N,N′-bis(naphthalene-1-yl)-N,N′-bis(phenyl)-2,2′-dimethylbenzidine), TPD(N,N′-bis-(3-methylphenyl)-N,N′-bis-(phenyl)-benzidine), s-TAD(2,2′,7,7′-tetrakis(N,N-dimethylamino)-9,9-spirofluorene), and MTDATA(4,4′,4″-Tris(N-3-methylphenyl-N-phenyl-amino)-triphenylamine), but is not limited thereto. The first hole transport layer can be omitted according to a structure or a characteristic of the element or can be configured by applying two or more layers or two or more materials.

The first emission layer is disposed between the first hole transport layer HTL1 and the first electron transport layer. The first emission layer is disposed at a location in the first light emitting unit 141 where an exciton is formed and can include a material which emits first light.

The first emission layer can be formed of a material which emits any one of red light, green light, and blue light. For example, the first emission layer can be a red emission layer. In this case, a wavelength range of light emitted from the red emission layer can be 600 nm to 650 nm.

The red emission layer can have a host-dopant system. The red emission layer can include a single host or a mixed host and at least one dopant. When the red emission layer includes a mixed host, the mixed host can include a hole-type host and an electron-type host. When the red emission layer is configured by the mixed host, the host can be uniformly deposited in the emission layer so that the efficiency of the emission layer can be improved.

The red emission layer can include a hole-type host and an electron-type host, but is not limited thereto. The red emission layer is doped with a red phosphorescent dopant material. The red phosphorescent dopant material is a material which is capable of emitting red light. An EL spectrum of light emitted from the red emission layer doped with the red phosphorescent dopant material can have a peak in a red wavelength band.

The host material of the red emission layer can include any one or more of anthracene derivatives, such as MADN(2-methyl-9,10-di(2-naphthyl) anthracene), NPD(N,N′-bis(naphthalene-1-yl)-N,N′-bis(phenyl)-2,2′-dimethylbenzidine), TPD(N,N′-bis-(3-methylphenyl)-N,N′-bis-(phenyl)-benzidine), spiro-TAD(2,2′,7,7′-tetrakis(N,N-dimethylamino)-9,9-spirofluorene), MTDATA(4,4′,4-Tris(N-3-methylphenyl-N-phenyl-amino)-triphenylamine), Alq3(tris(8-hydroxyquinolino)aluminum), Liq(8-hydroxyquinolinolato-lithium), PBD(2-(4-biphenylyl)-5-(4-tertbutylphenyl)-1,3,4oxadiazole), TAZ(3-(4-biphenyl)4-phenyl-5-tert-butylphenyl-1,2,4-triazole), spiroPBD, BAlq(bis(2-methyl-8-quinolinolate)-4-(phenylphenolato)aluminium), SAlq, TPBi(2,2′,2-(1,3,5-benzinetriyl)-tris(1-phenyl-1-H-benzimidazole), oxadiazole derivatives, triazole derivatives, phenanthroline derivatives, benzoxazole derivatives, or benzthiazole derivatives, but is not limited thereto.

The red phosphorescent dopant material of the red emission layer can include any one or more of a iridium (Ir) ligand complex including Ir(ppy)3(tris(2-phenylpyridine)iridium), PIQIr(acac) (bis(1-phenylisoquinoline) acetylacetonate iridium), PQIr(acac) (bis(1-phenylquinoline) acetylacetonate iridium), PQIr(tris(1-phenylquinoline) iridium), Ir(piq)3(tris(1-phenylisoquinoline)iridium), Ir(piq)2(acac) (bis(1-phenylisoquinoline) (acetylacetonate)iridium), pyran derivatives, such as PtOEP(octaethylporphyrinporphine platinum), PBD:Eu(DBM)3(Phen), and DCJTB(4-(dicyanomethylene)-2-tert-butyl-6-(1,1,7,7-tetramethyljulolidyl-9-enyl)-4H), boron derivatives, or perylene derivatives, but is not limited thereto.

The first electron transport layer is disposed on the first emission layer. The first electron transport layer is supplied with electrons from the first charge generation layer 142. The first electron transport layer ETL1 transmits the supplied electrons to the first emission layer. The first electron transport layer can serve as a hole blocking layer HBL. The hole blocking layer can suppress the holes which do not participate in the recombination from being leaked from the red emission layer.

For example, the first electron transport layer can be formed of any one or more of PBD(2-(4-biphenyl)-5-(4-tert-butylphenyl)-1,3,4-oxadiazole), TAZ(3-(4-biphenyl)-4-phenyl-5-tert-butylphenyl-1,2,4-triazole), BAlq(Bis(2-methyl-8-quinolinolate)-4-(phenylphenolato)aluminium), Liq(8-hydroxyquinolinolato-lithium), TPBi(2,2′,2″-(1,3,5-benzinetriyl)-tris(1-phenyl-1-H-benzimidazole), and BCP(2,9-Dimethyl-4,7-diphenyl-1,10-phenanthroline), but is not limited thereto.

The first charge generation layer (CGL) 142 is disposed between the first light emitting unit 141 and the second light emitting unit 143 which are adjacent thereto. Therefore, the first light emitting unit 141 and the second light emitting unit 143 can be supplied with charges from the first charge generation layer 142. For example, the first charge generation layer 142 can control a charge balance between the first light emitting unit 141 and the second light emitting unit 143. The first charge generation layer 142 can include an N-type charge generation layer and a P-type charge generation layer.

The N-type charge generation layer is disposed on the first electron transport layer to inject electrons to the first light emitting unit 141. The N-type charge generation layer can include an N-type dopant material and an N-type host material.

The N-type dopant material can be a metal of Group 1 and Group 2 on the periodic table, an organic material which can inject the electrons, or a mixture thereof. For example, the N-type dopant material can be any one of an alkali metal and an alkaline earth metal. For example, the N-type charge generation layer can be formed of an organic layer doped with an alkali metal such as lithium (Li), sodium (Na), potassium (K), or cesium (Cs) or an alkali earth metal such as magnesium (Mg), strontium (Sr), barium (Ba), or radium (Ra), but is not limited thereto.

The N-type host material can be formed of a material which is capable of transmitting electrons, for example, can be formed of any one or more of Alq₃(tris(8-hydroxyquinolino)aluminum), Liq(8-hydroxyquinolinolato-lithium), PBD(2-(4-biphenylyl)-5-(4-tert-butylphenyl)-1,3,4oxadiazole), TAZ(3-(4-biphenyl)4-phenyl-5-tert-butylphenyl-1,2,4-triazole), spiro-PBD, BAlq(bis(2-methyl-8-quinolinolate)-4-(phenylphenolato)aluminium), SAlq, TPBi(2,2′,2-(1,3,5-benzinetriyl)-tris(1-phenyl-1-H-benzimidazole), oxadiazole, triazole, phenanthroline, benzoxazole, and benzthiazole, but is not limited thereto.

The P-type charge generation layer is disposed on the N-type charge generation layer to inject holes into the second light emitting unit 143. The P-type charge generation layer can include a P-type dopant material and a P-type host material.

The P-type dopant material can be formed of metal oxide, an organic material such as tetrafluoro-tetracyanoquinodimethane (F4-TCNQ), HAT-CN (Hexaazatriphenylene-hexacarbonitrile), or hexaazatriphenylene, or a metal material such as V₂O₅, MoOx, and WO₃, but is not limited thereto.

The P-type host material can be formed of a material which is capable of transmitting holes, for example, can be formed of a material including any one or more of NPD(N,N-dinaphthyl-N,N′-diphenyl benzidine) (N,N′-bis(naphthalene-1-yl)-N,N′-bis(phenyl)-2,2′-dimethylbenzidine), TPD(N,N′-bis-(3-methylphenyl)-N,N′-bis-(phenyl)-benzidine), and MTDATA(4,4′,4-Tris(N-3-methylphenyl-N-phenyl-amino)-triphenylamine), but is not limited thereto.

The second light emitting unit 143 is disposed on the first charge generation layer 142. The second light emitting unit 143 includes a second hole transport layer, a second emission layer, and a second electron transport layer.

The second hole transport layer is disposed on the first charge generation layer 142. The second hole transport layer is an organic layer which smoothly transmits holes from the P-type charge generation layer to the second emission layer. The second hole transport layer is substantially the same as the first hole transport layer so that a redundant description will be omitted.

The second emission layer is sequentially disposed between the second hole transport layer and the second electron transport layer. The second emission layer is disposed at a location in the second light emitting unit 143 where an exciton is formed and can include a material which emits second light. The second emission layer can be formed of a material which emits any one of red light, green light, and blue light. For example, the second emission layer can be a blue emission layer. In this case, a wavelength range of light emitted from the blue emission layer can be 440 nm to 480 nm.

The blue emission layer can have a host-dopant system. For example, the blue emission layer can have a system in which an emission dopant material having a smaller weight ratio is doped on a host material which occupies a larger weight ratio. The host of the blue emission layer can be configured by a single material or a mixture host formed of mixed materials. A blue fluorescent dopant material is doped on the blue emission layer including a single host material or a mixed host material. The blue fluorescent dopant material is a material which is capable of emitting blue light. An EL spectrum of light emitted from the blue emission layer on which the blue fluorescent dopant material is doped can have a peak in a blue wavelength region, a peak in a dark blue wavelength region, or a peak in a sky blue wavelength region.

The host material of the blue emission layer can include any one or more of anthracene derivatives, such as TBSA(9,10-bis[(2″,7″-di-t-butyl)-9′,9″-spirobifluorenyl]anthracene), Alq3(tris(8-hydroxy-quinolino)aluminum), or ADN(9,10-di(naphth-2-yl)anthracene), BSBF(2-(9,9-spirofluoren-2-yl)-9,9-spirofluorene), CBP(4,4′-bis(carbazol-9-yl)biphenyl), spiro-CBP(2,2′,7,7′-tetrakis(carbazol-9-yl)-9,9′-spirobifluorene), mCP, and TcTa(4,4′,4-tris(carbazoyl-9-yl)triphenylamine, but is not limited thereto.

The blue fluorescent dopant material of the blue emission layer can be formed of a material containing any one or more of a pyrene in which an aryl amine-based compound is substituted, an iridium (Ir) ligand complex including FIrPic(bis(3,5-difluoro-2-(2-pyridyl)phenyl-(2-carboxyprdidyl) iridium) or Ir(ppy)3(tris(2-phenylpyridine)iridium), spiro-DPVBi, spiro-6P, spiro-BDAVBi(2,7-bis[4-(diphenylamino)styryl]-9,9′-spirofluorene), distyryl benzene (DSB), distyryl arylene (DSA), polyfluorene(PFO)-based polymer, and poly(p-phenylenevinylene) (PPV)-based polymer, but is not limited thereto.

The second electron transport layer is disposed on the second emission layer. The second electron transport layer is supplied with electrons from the second charge generation layer 144. The second electron transport layer transmits the supplied electrons to the second emission layer. The second electron transport layer is substantially the same as the first electron transport layer so that a redundant description will be omitted.

The second charge generation layer 144 is disposed between the second light emitting unit 143 and the third light emitting unit 145 which are adjacent thereto. The second charge generation layer 144 can control a charge balance between the second light emitting unit 143 and the third light emitting unit 145. The second charge generation layer 144 can include an N-type charge generation layer and a P-type charge generation layer. The second charge generation layer 144 is substantially the same as the first charge generation layer 142 so that a redundant description will be omitted.

The third light emitting unit 145 is disposed on the second charge generation layer 144. The third light emitting unit 145 includes a third hole transport layer, a third emission layer, and a third electron transport layer.

The third hole transport layer is disposed on the second charge generation layer 144. The third hole transport layer is an organic layer which smoothly transmits holes from the P-type charge generation layer to the third emission layer. The third hole transport layer is substantially the same as the first hole transport layer so that a redundant description will be omitted.

The third emission layer is sequentially disposed between the third hole transport layer and the third electron transport layer. The third emission layer is disposed at a location in the third light emitting unit 145 where an exciton is formed and can include a material which emits third light. The third emission layer can be formed of a material which emits any one of red light, green light, and blue light. For example, the third emission layer can be a green emission layer. In this case, a wavelength range of light emitted from the green emission layer can be 510 nm to 550 nm.

The green emission layer can include a hole-type host and an electron-type host, but is not limited thereto. The green emission layer is doped with a green phosphorescent dopant material. The green phosphorescent dopant material is a material which is capable of emitting green light. An EL spectrum of light emitted from the green emission layer doped with the green phosphorescent dopant material can have a peak in a green wavelength band.

The host material of the green emission layer can include any one or more of anthracene derivatives, such as TBSA(9,10-bis[(2″,7″-di-t-butyl)-9′,9″-spirobifluorenyl]anthracene), ADN(9,10-di(naphth-2-yl)anthracene), NPD(N,N′-bis(naphthalene-1-yl)-N,N′-bis(phenyl)-2,2′-dimethylbenzidine), TPD(N,N′-bis-(3-methylphenyl)-N,N′-bis-(phenyl)-benzidine), spiro-TAD(2,2′,7,7′-tetrakis(N,N-dimethylamino)-9,9-spirofluorene), MTDATA(4,4′,4-Tris(N-3-methylphenyl-N-phenyl-amino)-triphenylamine), Alq3(tris(8-hydroxyquinolino)aluminum), Liq(8-hydroxyquinolinolato-lithium), PBD(2-(4-biphenylyl)-5-(4-tert-butylphenyl)-1,3,4oxadiazole), TAZ(3-(4-biphenyl)4-phenyl-5-tert-butylphenyl-1,2,4-triazole), spiro-PBD, BAlq(bis(2-methyl-8-quinolinolate)-4-(phenylphenolato)aluminium), SAlq, TPBi(2,2′,2-(1,3,5-benzinetriyl)-tris(1-phenyl-1-H-benzimidazole), oxadiazole derivatives, triazole derivatives, phenanthroline derivatives, benzoxazole derivatives, or benzthiazole derivatives, but is not limited thereto.

The green phosphorescent dopant material of the green emission layer can include any one or more of a iridium (Ir) ligand complex including Ir(ppy)3(tris(2-phenylpyridine)iridium) or Alq3(tris(8-hydroxyquinolino)aluminum), but is not limited thereto.

The third electron transport layer is disposed on the third emission layer. The third electron transport layer is supplied with electrons from the second electrode 150. The third electron transport layer transmits the supplied electrons to the third emission layer. The third electron transport layer is substantially the same as the first electron transport layer so that a redundant description will be omitted.

In the meantime, the electron injection layer can be disposed between the third electron transport layer and the second electrode 150. The electron injection layer is an organic layer which smoothly injects the electrons from the second electrode 150 to the third emission layer. The electron injection layer can be formed of a material including any one or more of LIF, Al, MoO₃, LiQ(lithium quinolate), Alq3(tris(8-hydroxyquinolino)aluminum), PBD, TAZ, spiro-PBD, BAlq, or SAlq, but is not limited thereto.

The second electrode 150 is disposed on the third light emitting unit 145. The second electrode 150 can be formed as one layer over the front surface of the silicon substrate 110. For example, the second electrodes 150 of the first sub pixel SP1, the second sub pixel SP2, and the third sub pixel SP3 are connected to each other to be integrally formed. The second electrode 150 supplies electrons to the light emitting units 141, 143, and 145 so that the second electrode can be formed of a conductive material having a low work function. Specifically, the second electrode 150 can supply electrons to the third light emitting unit 145 among the light emitting units 141, 143, and 145. For example, the second electrode 150 can be formed of transparent conductive material, such as tin oxide (TO), zinc oxide (ZnO), indium tin oxide (ITO), indium zinc oxide (IZO), and indium tin zinc oxide (ITZO), or ytterbium (Yb) alloy. Further, the second electrode 150 can be formed of a metal material such as silver (Ag), copper (Cu), or a magnesium-silver alloy (Mg:Ag) or a metal material having a very thin thickness, but is not limited thereto.

The light emitting diode ED is an organic light emitting diode ED having a triple stack structure in which the first light emitting unit 141, the second light emitting unit 143, and the third light emitting unit 145 are laminated. Light which is finally emitted from the light emitting units 141, 143, and 145 can be implemented by mixing light emitted from the first light emitting unit 141, the second light emitting unit 143, and the third light emitting unit 145. Accordingly, a design in the light emitting units 141, 143, and 145 can vary depending on a color of light to be implemented.

The bank 160 is formed with a matrix structure in a boundary area between adjacent sub pixels SP1, SP2, and SP3. Further, one end of the bank 160 is provided to be in contact with an inlet of the trench T or spaced apart from the inlet of the trench T with a predetermined distance.

Further, the bank 160 can be formed to cover both ends of the first electrode 130 provided in the first to third sub pixels SP1, SP2, and SP3. Accordingly, an exposed area of the first electrode 130 which is not blocked by the bank 160 to be exposed serves as an emission area.

Further, the bank 160 is formed to cover a part of a top surface and a side surface of an end of the first electrode 130 so that the degradation of the luminous efficiency caused by the current which is concentrated at the end of the first electrode 130 can be suppressed. Further, the bank 160 can be formed of an inorganic insulating film. For example, the bank 160 can be formed of a silicon oxide film (SiOx) or a silicon nitride film (SiNx), or multiple films thereof, but is not limited thereto.

The bank 160 can be configured by a plurality of layers. The bank 160 is formed of at least two or more layers. When the light emitting diode ED has a stack structure in which the plurality of light emitting units 141, 143, and 145 is laminated, the plurality of banks 160 can be configured with the number of which is equal to or larger than the number of laminated light emitting units which configure the light emitting diode ED. For example, when the light emitting diode ED has a triple stack structure including the first light emitting unit 141, the second light emitting unit 143, and the third light emitting unit 145, the bank 160 can be configured by triple or more layers. Referring to FIG. 2, the bank 160 includes a first inorganic bank layer 161, a second inorganic bank layer 162, and a third inorganic bank layer 163. In FIG. 2, the light emitting diode ED has a triple stack structure having three light emitting units 141, 143, and 145 so that a structure in which the bank 160 is formed by triple layers has been illustrated. However, when the light emitting diode ED has a stack structure having two light emitting units, the bank 160 can be formed with a double-layered structure.

The bank 160 includes a step formed on both ends by the plurality of layers. Referring to FIG. 3, the bank 160 has a structure in which the first inorganic bank layer 161, the second inorganic bank layer 162, and the third inorganic bank layer 163 are sequentially laminated. At this time, the second inorganic bank layer 162 disposed on the first inorganic bank layer 161 is disposed to have a width smaller than that of the first inorganic bank layer 161. By doing this, a first step S1 is formed on both ends of the first inorganic bank layer 161 and the second inorganic bank layer 162. Further, the third inorganic bank layer 163 disposed on the second inorganic bank layer 162 is disposed to have a width smaller than that of the second inorganic bank layer 162. By doing this, a second step S2 is formed on both ends of the second inorganic bank layer 162 and the third inorganic bank layer 163.

The first step S1 and the second step S2 formed by the first to third inorganic bank layers 161, 162, and 163 disconnect the light emitting units 141, 143, and 145 of the light emitting diode ED.

Specifically, referring to FIG. 3, the organic material layer 140 and the second electrode 150 which configure the light emitting diode ED can be a common layer which is formed as one layer over the front surface of the silicon substrate 110. At this time, the organic material layer 140 is disposed on the first electrode 130 and the bank 160. The organic material layer 140 can be disconnected between layers which configure the organic material layer 140 by the first step S1 and the second step S2 formed on the bank 160.

To be more specific, the first light emitting unit 141, the second light emitting unit 143, and the third light emitting unit 145 are disposed on the first inorganic bank layer 161 and the second inorganic bank layer 162, respectively, to be disconnected due to the height of the first step S1, without being continued. Likewise, the first charge generation layer 142 and the second charge generation layer 144 are also disposed on the first inorganic bank layer 161 and the second inorganic bank layer 162 to be disconnected due to the height of the first step S1, without being continued. Further, the first light emitting unit 141, the second light emitting unit 143, and the third light emitting unit 145 are disposed on the second inorganic bank layer 162 and the third inorganic bank layer 163 to be disconnected due to the height of the second step S2, without being continued. Likewise, the first charge generation layer 142 and the second charge generation layer 144 are also disposed on the second inorganic bank layer 162 and the third inorganic bank layer 163, respectively, to be disconnected due to the height of the second step S2, without being continued.

In the meantime, a thickness d2 of each of the first to third inorganic bank layers 161, 162, and 163 can be larger than a thickness of the first light emitting unit 141 and a thickness of the second light emitting unit 143. As the thickness of each of the first to third inorganic bank layers 161, 162, and 163 is larger than a thickness of the light emitting unit so that a step height sufficient to disconnect common layers which configure the light emitting unit can be formed. However, it is not limited thereto and the thickness of each of the first to third inorganic bank layers 161, 162, and 163 is smaller than a thickness of the light emitting unit, but the first to third inorganic bank layers 161, 162, and 163 can be formed to have a height sufficient to disconnect the first charge generation layer 142 and the second charge generation layer 144.

In the meantime, a width d1 of top surfaces of the inorganic bank layers 161 and 162 which are exposed by the steps S1 and S2 can be larger than the thickness of the inorganic bank layers 161 and 162. For example, a width d1 of a top surface of the first inorganic bank layer 161 which is exposed by the first step S1 can be larger than a thickness d2 of the first inorganic bank layer 161, but is not limited thereto. A width d1 of the top surface of each inorganic bank layer which is exposed by the step can vary according to a type of a material which configures the light emitting unit, and deposition equipment or condition.

The bank 160 is formed by laminating a plurality of inorganic bank layers 161, 162, and 163 with different widths to disconnect the light emitting units 141, 143, and 145 or the charge generation layers 142 and 144. By doing this, a lateral leakage current generated on the bank 160 can be suppressed. Specifically, the charge generation layers 142 and 144 can include a conductive material to easily move charges. Accordingly, the first charge generation layer 142 and the second charge generation layer 144 which are formed as a common layer are disconnected by the steps S1 and S2 formed by the plurality of inorganic bank layers 161, 162, and 163. Further, the charge movement from the charge emission area onto the bank 160 through the first charge generation layer 142 and the second charge generation layer 144 is reduced to suppress the leakage current.

In the meantime, in the boundary area between the sub pixels SP1, SP2, and SP3, the trench T is formed on the bank 160 together with the insulating layer 125. For example, the trench T passes through the first to third inorganic bank layers 161, 162, and 163 between the first sub pixel SP1 and the second sub pixel SP2, and can extend to a predetermined area in the insulating layer 125 without passing through the insulating layer 125. However, any one inorganic bank layer, among the first to third inorganic bank layers 161, 162, and 163 can be spaced apart from the trench T.

A part of the organic material layer 140 which configures the light emitting diode ED can be disconnected by the trench T. For example, the first light emitting unit 141, the second light emitting unit 143, and the third light emitting unit 145 can be disconnected by the trench T without being connected to the adjacent sub pixels SP1, SP2, and SP3. Likewise, the first charge generation layer 142 and the second charge generation layer 144 can also be disconnected by the trench T without being connected to the adjacent sub pixels SP1, SP2, and SP3. In FIG. 3, a structure in which all the first light emitting unit 141, the second light emitting unit 143, the third light emitting unit 145, the first charge generation layer 142, and the second charge generation layer 144 which configure the organic material layer 140 are disconnected by in the trench has been illustrated. However, only the first charge generation layer 142 and the second charge generation layer 144 are disconnected, and some configurations of the first light emitting unit 141, the second light emitting unit 143, and the third light emitting unit 145 can be connected to each other.

The trench T does not allow charges to move through the first charge generation layer 142 and the second charge generation layer 144, between the first sub pixel SP1 and the second sub pixel SP2 and between the second sub pixel SP2 and the third sub pixel SP3. Therefore, the leakage current generated between adjacent sub pixels can be suppressed.

The encapsulation layer 170 can be located on the light emitting diode ED. The encapsulation layer 170 can have a single layer structure or a multi-layered structure. For example, the encapsulation layer 170 can include a first encapsulation layer 171, a second encapsulation layer 172, and a third encapsulation layer 173.

The first encapsulation layer 171 is disposed on the second electrode 150 and can be disposed to be most adjacent to the light emitting diode ED. The first encapsulation layer 171 can be formed of an inorganic insulating material on which low-temperature deposition can be performed. For example, the first encapsulation layer 171 can be configured by silicon nitride (SiNx), silicon oxide (SiOx), silicon oxynitride (SiON), or aluminum oxide Al₂O₃. The first encapsulation layer 171 is deposited under a low temperature atmosphere so that during the deposition process, the damage of the light emitting units 141, 143, and 145 including an organic material which is vulnerable to the high temperature atmosphere can be suppressed.

The second encapsulation layer 172 can be formed to have a smaller area than that of the first encapsulation layer 171. In this case, the second encapsulation layer 172 can be formed to expose both ends of the first encapsulation layer 171. The second encapsulation layer 172 can serve as a buffer to alleviate stress between the respective layers due to bending of the flexible display device and to enhance planarization performance. For example, the second encapsulation layer 172 can be formed of an organic insulating material, such as acrylic resin, epoxy resin, polyimide, polyethylene, or silicon oxy carbon (SiOC). For example, the second encapsulation layer 172 can be formed by an inkjet method, but is not limited thereto.

The third encapsulation layer 173 can be formed above the silicon substrate 110 on which the second encapsulation layer 172 is formed so as to cover top surfaces and side surfaces of the second encapsulation layer 172 and the first encapsulation layer 171. At this time, the third encapsulation layer 173 can minimize or block the permeation of external moisture or oxygen into the first encapsulation layer 171 and the second encapsulation layer 172. For example, the third encapsulation layer 173 can be configured by an inorganic insulating material, such as silicon nitride (SiNx), silicon oxide (SiOx), silicon oxynitride (SiON), or aluminum oxide Al₂O₃.

The color filter 180 is disposed on the encapsulation layer 170. The color filter 180 can be disposed so as to correspond to each of the sub pixels SP1, SP2, and SP3. The color filter 180 can convert white light emitted from the light emitting units 141, 143, and 145 of the light emitting diode ED into light having a specific color. Specifically, the first sub pixel SP1 can be a blue sub pixel so that the color filter 180 can be a blue color filter. Further, the second sub pixel SP2 is a green sub pixel so that the color filter 180 can be a green color filter. Further, the third sub pixel SP3 is a red sub pixel so that the color filter 180 can be a red color filter. White light emitted from the light emitting units 141, 143, and 145 can be converted into red light, green light, and blue light by the color filters 180 of the corresponding sub pixels SP1, SP2, and SP3.

When the distance between the emission layer and the metal layer is short, the emitted light can become extinct due to the surface plasmon polariton (SPP). This phenomenon is most critical in the emission layer closest to the reflective layer, which can cause light loss in the corresponding emission layer. Specifically, among light emitted from the emission layer, light which is incident onto the reflective layer becomes extinct due to the SPP and the luminous efficiency can be degraded. A general OLEDoS organic light emitting display device is formed with a tandem structure using two stacks and the blue emission layer can be disposed on a lower stack close to the first electrode. Generally, the blue emission layer which is a fluorescent emission layer has a lower efficiency than the red emission layer and the green emission layer which are phosphorescent emission layers. Further, the blue emission layer is disposed to be closer to the reflective layer than the red emission layer and the green emission layer so that the light loss due to the SPP can be significant. Therefore, the OLEDoS organic light emitting display device has a disadvantage that the efficiency of the blue emission layer is significantly degraded. This can lead the reduction in the luminous efficiency in the blue sub pixel which emits blue light, which can degrade the quality of the organic light emitting display device.

In the display device with a tandem structure of two or more stacks in which two or more emission layers are laminated, a plurality of common layers is formed so that the current can be leaked from any one sub pixel to an adjacent sub pixel. Therefore, the display device has problems in that unwanted color light is emitted due to the leakage current and the color gamut can be degraded and the lifespan can be shortened.

In the display device according to the example embodiment of the present disclosure, a trench is formed in the insulating layer and the bank between the sub pixels to disconnect the light emitting unit or the charge generation layer to suppress the leakage current generated between sub pixels.

Further, in the display device according to the example embodiment of the present disclosure, a step is formed by a plurality of inorganic bank layers with different widths to disconnect the light emitting unit or the charge generation layer laminated on the inorganic bank layer. By doing this, a lateral leakage current is generated on the bank in one sub pixel so that a problem in that an emission layer on the bank which is not the emission area emits light can be solved.

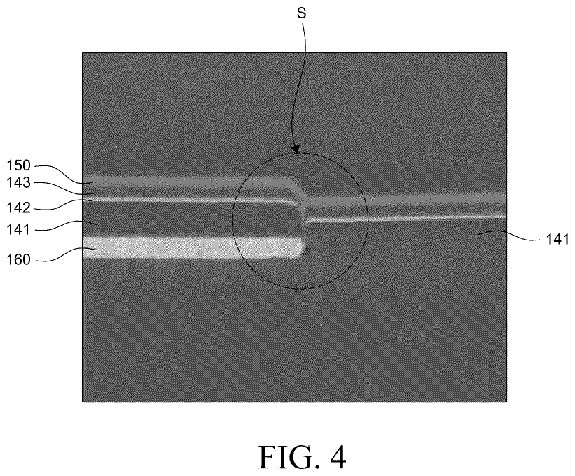

FIG. 4 is an image obtained by capturing a cross-section of a display device according to an example embodiment of the present disclosure. Here, the display device of the present disclosure is used.

Referring to FIG. 4, it is confirmed that when a bank 160 in which a plurality of inorganic bank layers was laminated was disposed below the first light emitting unit 141, the first charge generation layer 142, and the second light emitting unit 143, the first charge generation layer 142 and the second light emitting unit 143 were disconnected by the step S, unlike the first light emitting unit 141.

The example embodiments of the present disclosure can also be described as follows:

According to an aspect of the present disclosure, there is provided a display device. The display device includes a silicon substrate including a plurality of sub pixels; an insulating layer on the silicon substrate; a light emitting diode disposed so as to correspond to each of the plurality of sub pixels, and including a first electrode disposed on the insulating layer, an organic material layer on the first electrode, and a second electrode on the organic material layer; and a plurality of inorganic bank layers covering an edge of the first electrode. The plurality of inorganic bank layers is adjacent to at least the first electrode to form a step.

The plurality of inorganic bank layers can include a first inorganic bank layer and a second inorganic bank layer disposed on the first inorganic bank layer, and a width of the second inorganic bank layer can be smaller than a width of the first inorganic bank layer.

The organic material layer can include a first light emitting unit on the first electrode, a first charge generation layer on the first light emitting unit, and a second light emitting unit on the first charge generation layer, and the first light emitting unit can be disposed on a top surface of the first inorganic bank layer exposed by the second inorganic bank layer.

At least one of the first light emitting unit, the first charge generation layer, and the second light emitting unit can be disconnected on the plurality of inorganic bank layers due to the step.

A thickness of each of the first inorganic bank layer and the second inorganic bank layer can be larger than a thickness of the first light emitting unit and a thickness of the second light emitting unit.

A width of the exposed top surface of the first inorganic bank layer can be larger than a thickness of the first inorganic bank layer.

The display device can further comprise a trench formed in the insulating layer at a boundary between adjacent sub pixels.

One ends of the plurality of inorganic bank layers can be in contact with an inlet of the trench.

The trench can have a shape extending so as to pass through the plurality of inorganic bank layers.

The organic material layer can include a first light emitting unit on the first electrode, a first charge generation layer on the first light emitting unit, and a second light emitting unit on the first charge generation layer, and at least one of the first light emitting unit, the first charge generation layer, and the second light emitting unit can be disconnected in the trench.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto.

Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a silicon substrate including a plurality of sub pixels;
an insulating layer on the silicon substrate;
a light emitting diode disposed to correspond to each of the plurality of sub pixels, and including a first electrode disposed on the insulating layer, an organic material layer on the first electrode, and a second electrode on the organic material layer; and
a plurality of inorganic bank layers covering an edge of the first electrode,
wherein the plurality of inorganic bank layers is disposed adjacent to at least the first electrode to form a step.

2. The display device according to claim 1, wherein the plurality of inorganic bank layers includes a first inorganic bank layer and a second inorganic bank layer disposed on the first inorganic bank layer, and
wherein a width of the second inorganic bank layer is smaller than a width of the first inorganic bank layer.

3. The display device according to claim 2, wherein the organic material layer includes a first light emitting unit on the first electrode, a first charge generation layer on the first light emitting unit, and a second light emitting unit on the first charge generation layer, and
wherein the first light emitting unit is disposed on a top surface of the first inorganic bank layer exposed by the second inorganic bank layer.

4. The display device according to claim 3, wherein at least one of the first light emitting unit, the first charge generation layer, and the second light emitting unit is disconnected on the plurality of inorganic bank layers due to the step.

5. The display device according to claim 3, wherein a thickness of each of the first inorganic bank layer and the second inorganic bank layer is larger than a thickness of the first light emitting unit and a thickness of the second light emitting unit.

6. The display device according to claim 3, wherein a width of the exposed top surface of the first inorganic bank layer is larger than a thickness of the first inorganic bank layer.

7. The display device according to claim 1, further comprising:
a trench formed in the insulating layer at a boundary between adjacent sub pixels among the plurality of sub pixels.

8. The display device according to claim 7, wherein one ends of the plurality of inorganic bank layers are in contact with an inlet of the trench.

9. The display device according to claim 8, wherein the trench has a shape extending to pass through the plurality of inorganic bank layers.

10. The display device according to claim 8, wherein the organic material layer includes a first light emitting unit on the first electrode, a first charge generation layer on the first light emitting unit, and a second light emitting unit on the first charge generation layer, and
wherein at least one of the first light emitting unit, the first charge generation layer, and the second light emitting unit is disconnected in the trench.
